(19) United States
(12) Patent Application Publication
(10) Pub. No.: US 2012/0248034 A1
(43) Pub. Date: Oct. 4, 2012

(54) METHODS OF MAKING AND USING LIQUID FILTER MEDIA

(75) Inventors: PAUL N. SEGIT, DOVER, NH (US); ROBERT A. CHENEY, JR., FARMINGTON, NH (US); DAVID R. LAMBERT, ROCHESTER, NH (US)

(73) Assignee: LYDALL, INC., MANCHESTER, CT (US)

(21) Appl. No.: 13/427,402

(22) Filed: Mar. 22, 2012

Related U.S. Application Data
(60) Provisional application No. 61/470,634, filed on Apr. 1, 2011.
(60) Provisional application No. 61/492,517, filed on Jun. 2, 2011.

(51) Int. Cl. B01D 39/20; C23C 16/50; B01D 39/14

(52) U.S. Cl. 210/504; 210/508; 210/509; 427/569; 162/145

(57) ABSTRACT

Filtration media for filtering a liquid includes a plurality of fibers having a coating thereon of a fluorine containing compound. Also disclosed are processes for forming fibrous non-woven liquid filtration media having the coating of the fluorine containing compound. Suitable fluorine containing compounds generally include fluoropolymers, fluorinated hydrocarbons, fluoroacrylate polymers, and the like. The liquid filtration media having the coating of the fluorine containing compound provides markedly improved dirt holding capacity and efficiency properties, among others.

### CROSS-REFERENCE TO RELATED PATENT APPLICATIONS

This application claims the benefit of U.S. Provisional Application Ser. No. 61/470,634 filed Apr. 1, 2011, and U.S. Provisional Application Ser. No. 61/492,517, filed Jun. 2, 2011, which are incorporated herein by reference in their entirety.

### BACKGROUND

This disclosure generally relates to a liquid filtration media and methods of making and using same. More specifically, the disclosure relates to a liquid filter media having improved contaminant removal characteristics, for example, in hydraulic filter applications.

Filtration is generally known for the removal of contaminants and/or impurities from a fluid, which can be air or liquid based. Air filtration media is generally defined by its surface attraction properties, i.e., retention properties, whereas liquid filtration media relies on a straining mechanism that is generally controlled by pore size. There is no correlation between air filtration and liquid filtration, each must be quantified independently, even if removing the same contaminant. For example, particle retention in air is affected by several factors such as inertial impaction, interception, diffusion, and electrostatic attraction. Liquids, on the other hand, tend to rely on pore size for capture efficiency.

One type of filtration involves passing a fluid through a filter having a fine physical barrier, which may be effective to remove at least a portion of the contaminants (for example, particulate matter) from a fluid passed therethrough. The performance characteristics of a filter are generally a function of the filter media employed within that filter and its geometry. The filter media refers to the fine physical barrier through which a fluid is passed to remove at least a portion of the contaminants from the fluid. The geometry refers to, in large part, the exposed surface area of the filter—that is, the surface area of the filter media with which the fluid being filtered comes into contact. Exposed surface area can be increased by, for example, folding or pleating the filter media to increase the effective surface area of a filter without substantially increasing the volume of the filter.

In practice, a filter media is typically subjected to a continuous flow of a fluid, and therefore, is exposed to contaminants entrained, dissolved, or otherwise carried in the fluid. The filter media may remove/retain from the fluid at least a portion of the contaminants that are of a size, shape, and/or affinity for that filter media as the fluid passes through the filter media until the filter media becomes coated or clogged with contaminant to the extent that the flow of fluid therethrough is restricted, often indicated by reaching a differential pressure across the filter media. Such coating or clogging of a filter with contaminant typically necessitates that the filter and/or the filter media be cleaned or replaced.

Enhanced filter media performance may provide improved filtration and/or filter performance and, thereby, increased system reliability, longevity, and uptime while lowering costs associated with operation. Therefore, a need exists for an improved fluid filtration media.

### BRIEF SUMMARY

Disclosed herein are liquid filtration media for filtering liquids and methods for forming the liquid filtration media. In one embodiment, a wet laid non-woven liquid filtration media for filtering liquids comprises a plurality of fibers having a coating thereon of a fluorine containing compound.

The method of forming fibrous non-woven liquid filtration media comprises dispersing fibers in a liquid to form a furnish; subjecting the furnish to a moving forming screen to form a fibrous web; applying a binder to the fibrous web; drying the fibrous web to form a fibrous non woven mat, wherein a fluorine containing compound is supplied in the furnish; and incorporating the fibrous non woven mat into the fibrous non woven liquid filtration media.

In another embodiment, a method of forming fibrous non-woven liquid filtration media comprises exposing a gas comprising a fluorine containing compound to an energy source to form a plasma; and exposing fibers defining the non-woven liquid filtration media to the plasma to form a coating of the fluorine containing compound on the fibers.

The disclosure may be understood more readily by reference to the following detailed description of the various features of the disclosure and the examples included therein.

### BRIEF DESCRIPTION OF THE DRAWINGS

FIG. 1 is a flowchart according to one or more embodiments of a filtration media forming method; and

FIG. 2 is a flowchart of a filtration media forming method in accordance with another embodiment of the invention.

### DETAILED DESCRIPTION

Disclosed herein are liquid filtration media and methods of making and using the same. As used herein, the terms “filtration media,” “filter media,” or “media” may occasionally be used interchangeably. In an embodiment, the filter media generally comprises fibers that have been formed into a wet-laid, non-woven fibrous mat, composite, web, or matrix (WNM), wherein the liquid filtration media, the fibers thereof, or both have been treated with a fluorine-containing compound (FCC) to form a coating thereon, referred to as an FCC-treated WNM. The FCC-treated WNM may further comprise various other binders, additives, treatments, or combinations thereof as may conventionally be used in the art. Advantageously, the FCC-treated WNM exhibits enhanced efficiency and/or dirt-holding capacity (DHC) when employed in liquid filtration, among other properties.

In an embodiment, the fibers of the liquid filtration media may comprise any fiber or combination of fibers suitable for providing a relatively high surface area, nonwoven, fibrous mat. For example, in an embodiment, the fibers may comprise glass fibers (for example, as are commercially available), natural fibers, polymeric synthetic fibers, ceramic fibers, metallic fibers, carbon fibers, various other fibers, or combinations thereof. Examples of suitable types of glass fibers include E-glass fibers (alumino-borosilicate glass having less than 1 wt % alkali oxides), A-glass fibers (alkali-lime glass with little or no boron oxide), E-CR-glass fibers (alumino-lime silicate with less than 1 wt % alkali oxides), C-glass fibers (alkali-lime glass with relatively high boron oxide content), D-glass fibers (borosilicate glass), R-glass (alumino silicate glass without MgO and CaO), and S-glass fibers (alumino silicate glass without CaO but with high MgO content). Non-limiting examples of other types of fibers include cellulosic fibers such as those fibers derived from pulped wood or plant material (e.g., switchgrass or hemp) and cotton fibers, meta-aramid fibers, para-aramid fibers, polymeric fibers such as polyphenylene sulfide, poly(butylene terephthalate), poly(ethylene terephthalate), polypropylene, or polyethylene fibers, clay fibers (e.g., any clay body to which processed cellulosic fibers have been added), and fluorochemical fibers such as polytetrafluoroethylene (PTFE).

In an embodiment, the fibers may be of any suitable size and/or shape, particularly, of a size and/or shape that may accommodate a given application and/or yield a given set of filter media parameters, as one of ordinary skill in the art would appreciate, having the benefit of the present disclosure.

In an embodiment, the fiber may be present in the filter media in an amount, by total weight of the solid material, of from about 50 weight percent (wt. %) to about 95 wt. %, alternatively from about 65 wt. % to about 90 wt. %, and alternatively from about 75 wt. % to about 85 wt. %.

In an embodiment, the FCC with which the filter media, the fibers thereof, or both are treated to form a coating thereon may comprise any suitable FCC. Non-limiting examples of suitable FCC's include fluoropolymers, fluorinated hydrocarbons, fluoroacrylate polymers, fluoroalkyl acrylate polymers, fluoroalkyl methacrylate polymers, perfluoroalkyl methylacrylate copolymers, or combinations thereof. Non-limiting examples of suitable FCCs include polytetrafluoroethylene (PTFE), perfluoroalkoxy polymer (PFA), fluorinated ethylene-propylene (FEP), or combinations thereof. In an embodiment, a suitable FCC for treating the fibers and/or the filter media comprises PTFE dispersed in water. For example, the PTFE may be readily dispersed in water and thermally flocked to the fibers at an elevated temperature. A non-limiting example of an FCC suitable for use in this disclosure is available under the trade name Teflon 30B, which is a PTFE dispersion commercially available from DuPont.

In an embodiment as will be described herein below, the FCC may be applied to and/or contacted with the fibers that will be formed into a filter media in any suitable amount. In an embodiment, the amount of FCC applied to and/or contacted with the fibers may be dependent upon the stage of a filter-media-forming process as will be disclosed herein.

In an embodiment, the FCC may be applied to and/or contacted with the fibers that will be formed into the filter media at a rate of from about 1% to about 25%, by percent of the FCC per dry weight of the solid material, alternatively, from about 5% to about 20%, alternatively, from about 10% to about 15%.

Without wishing to be limited by theory, it is thought that application of a suitable FCC may coat and/or adhere to the fibers of the filter media and thereby modify the surface energy of those fibers. As such, for example, application of the FCC to the filter media and/or the fibers thereof yields an FCC-treated WNM, exhibiting a substantially enhanced ability to efficiently capture and retain contaminant particles and/or repel the contaminant particles from the media and not allow them to pass through relative to the same media without the FCC coating.

In an embodiment, the fibers of the filter media may further be treated with one or more commercially available binders. Without wishing to be limited by theory, the binder may facilitate the formation of the filter media by bonding and/or adhering the fibers thereof; facilitate the interaction and adhesion of the fiber component and FCC; facilitate dispersion of the FCC throughout the filter media; and/or provide additional tensile and elongation characteristics to the filter media. The binder may comprise any material capable of performing one or more of these functions so long as the binder is compatible with the other components defining the filter media.

Suitable binders include, without limitation, an emulsion polymer, resins, solution polymers, or combinations thereof. Non-limiting examples of a suitable binder element include styrene-acrylates, styrene-butadiene, acrylics, vinyl acetates, acrylonitriles, urethanes, epoxies, urea formaldehyde, melamine formaldehyde, acidified acrylates, polyvinyl alcohol, or combinations thereof. In an embodiment, the binder comprises a polymer that has been modified to comprise one or more functional groups. For example, the polymer may be functionalized to contain additional carboxylates.

In an alternative embodiment, the binder comprises a carboxylated polymer, a polyalcohol crosslinking agent, and an optional dispersion component. The carboxylated polymer may comprise a carboxylated styrenic polymer, a carboxylated styrene-acrylate copolymer, a highly carboxylated styrenic polymer, a highly carboxylated styrene-acrylate copolymer, or combinations thereof. An example of a suitable binder includes HYCAR® 26172, which is an acrylic ester copolymer commercially available from Lubrizol. In another embodiment, the binder comprises a water based binder that may be thermally cured.

The binder is typically present in the filter media in an amount, by total weight of the solid material, of from about 3 wt. % to about 40 wt. %, alternatively from about 5 wt. % to about 25 wt. %, and still alternatively from about 10 wt. % to about 20 wt. %.

In an embodiment, the FCC treated fibers and/or filter media may further comprise and/or be treated with one or more suitable additives. Such additives may impart various desired properties and/or alter the performance of the filter media. Examples of suitable additives include but are not limited to a colorants, pigments/dyes, biocides, absorbents, stabilizers, chain transfer agents, antioxidants, ultra-violet screening agents, anti-static agents, the like, or combinations thereof.

In various embodiments, the FCC-treated WNM may be characterized by one or more performance metrics. Examples of such performance metrics include, but are not limited to efficiency, dirt holding capacity (DHC), pressure drop across the filter media, and/or various other metrics. As will be appreciated by those skilled in the art, a beta ratio is often calculated to characterize efficiency, wherein a high beta ratio is generally indicative of high efficiency. Beta ratio is defined as the ratio of the number of particles at a given size upstream of the filter media to the number of particles at the given size downstream of the filter. A caliper can be used to measure thickness at a defined pressure, e.g., 8 psi. The degrees of penetration (DOP) tests can be conducted in accordance with using industry standard ASTM D2986/MIL-STD 282 using a Q127 penetrometer. In an embodiment, the FCC-treated WNM may be characterized as exhibiting an improved efficiency. In another embodiment, the FCC-treated WNM may be characterized as exhibiting an improved DHC. DHC generally refers to a measure of the quantity of contaminant that a given filter media can trap and hold before the maximum allowable pressure drop across the filter is reached. The improvements are relative to the same media without treatments with the FCC.

For purposes of assessing one or more of such performance metrics, the filter media may be employed in a liquid filtration operation, for example, in an industrial setting, in a “benchtop” test setting, or in any setting by which some performance characteristics of the filter media may be evaluated or assessed. The filter media may then be subjected to a flow of a liquid. Such a test liquid may be intentionally provided with a known quantity of contaminants of a specified size and/or shape. In addition, a means or device for counting or otherwise measuring the number of particles removed from the liquid by the filter media may be provided. Typically, particulate matter entrained in the test liquid may be monitored before and after passing across the filter media during testing. Alternatively, particles in the liquid may be measured before and after testing, in order to acquire similar information. The efficiency of the liquid filter media may then be estimated in terms of the quantity and size of the particles removed from the fluid by the liquid filter media. An example of such a test, which is designed to evaluate the efficiency and DHC of filters, is described in ISO 168889, Multi-pass method for evaluating filtration performance of a filter element, which is incorporated herein by reference in its entirety.

In an embodiment, the FCC-treated WNM may exhibit an efficiency of about 99.5% or more on particles of size ranging from about 4 microns to about 60 microns or more; alternatively from about 10 microns to about 50 microns, as measured in accordance with ISO 168889. The efficiency of 99.5% is equivalent to a beta ratio of about 200. Filter resistance (sometimes referred to as pressure drop) is the effect that a filter has on fluid flow. As a filter media becomes plugged with contaminant particles, the pressure drop increases. Not intending to be bound by theory, higher pressure drops tend to decrease the operating lifetime of the filtration systems, and a lower pressure drop may allow the equipment to operate for longer period of times. In an embodiment, the FCC-treated WNM may exhibit a given efficiency at a lower resistance (i.e., pressure drop) as compared to an otherwise similar, non FCC-treated WNM.

The weight of contaminant particles collected per unit area of filter media before a specified pressure drop increase from its initial value is reached is referred to as the DHC. In an embodiment, the filter media may exhibit a DHC of from about 120 g/m2 to about 300 g/m2 or more; alternatively from about 150/m2 to about 250 g/m2, alternatively about 180/m2 to about 240 g/m2, as measured in accordance with ISO 168889 up to a pressure drop increase of 2 bars from its initial clean value.

In an embodiment, the FCC-treated WNM may be characterized as exhibiting a water repellency value, of from about 3 mm to greater then 40 mm, when measured in accordance with MIL-STD-282 (water rep), alternatively, from about 5 mm to about 35 mm, alternatively, from about 10 mm to about 30 mm.

In an embodiment, the filter media (e.g., the FCC-treated WNM) may be characterized as a mat, composite, web, or matrix and may be formed from one or more layers of a wet-laid nonwoven material. A composite generally refers to a material resulting from the bonding together or joining of two or more components. The filter media may be formed into a composite by mechanically, chemically, or thermally bonding the fibers together. In an embodiment, the fibers, the FCC, and, when present, binding agents and/or additives may be comingled, blended, mixed or otherwise brought together, for example, via a modified wet-laid nonwoven process as will be disclosed herein, to form the filter media. Processes for forming wet-laid, nonwoven fiber mats for filtration applications are described in U.S. Pat. No. 6,579,350 and U.S. Patent Publication 2006/0277877, both of which are hereby incorporated by reference in their entirety.

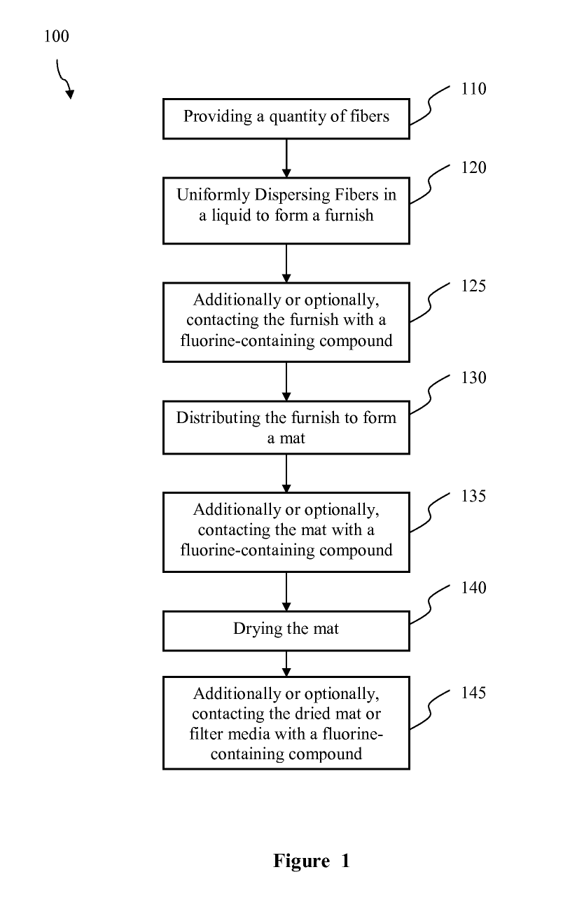

Referring to FIG. 1, one or more embodiments of a filter media-forming (FMF) process 10 are illustrated. In the embodiment of FIG. 1, the FMF 100 process generally comprises providing a quantity of fibers at Block 110, uniformly dispersing fibers in a suitable liquid to form a furnish at Block 120, additionally or optionally, contacting the furnish with a fluorine-containing compound at Block 125, distributing the furnish to form the mat at Block 130, additionally or optionally, contacting the mat with a fluorine-containing compound at Block 135, drying the mat to remove any liquid 140, and, additionally or optionally, contacting the dried mat with a fluorine-containing compound at Block 145. It should be noted that the designation of the various steps in which an FCC is contacted with the fibers, the furnish, the mat, or the filter media as either “optionally” or “additionally or optionally” should be construed to mean that an FCC is contacted with at least one of the filter media, the fibers thereof, or combinations thereof at any one or more of multiple points during the performance of a filter media-forming process, as will be discussed herein. For example, in the embodiment of FIG. 1, the filter media, the fibers thereof, or combinations thereof may be brought into contact with a suitable FCC at Blocks 125, 135, 145, or combinations thereof. As will be described herein, in the embodiment of FIG. 1 the filter media and/or the fibers thereof may be sprayed with, soaked in, saturated with, coated, or otherwise brought into contact with the FCC, as may be suitable dependent upon the stage of the overall process.

In the embodiment of FIG. 1, the fibers, are first dispersed in a liquid to form the furnish at Block 120. As used herein, the furnish generally refers to a slurry comprising a quantity of fibers dispersed in a suitable liquid. The liquid in which the fibers are dispersed may be any suitable liquid. Typically, the furnish is water based although other liquids can be used as will be appreciated by one of skill in the art. For example, one or more components of the filter media may be suspended in water to form the furnish. The water may be fresh water or mill water, wherein mill water refers to water recycled from a papermaking or similar process. The water in the furnish may be present in an amount of from about 97% to about 99.95% based on a wet weight basis, alternatively from about 97.5% to about 99%, alternatively from about 97.75% to about 98.75%. In an embodiment, the water constitutes the remainder of the slurry/dispersion when all other components of the furnish are accounted for. In an embodiment, some additives in addition to the FCC may be included within the furnish. The furnish may be mixed, agitated, stirred, or the like to ensure that the components present therein are uniformly or substantially distributed.

In the embodiment of FIG. 1, additionally or optionally, the furnish may be contacted with an FCC at Block 125. In an embodiment where the furnish is contacted with an FCC, the FCC may be contacted with the furnish in any suitable fashion. For example, the FCC may be added to and/or incorporated as a component of the furnish, and thereby contacted with the fibers within the furnish. In an alternative embodiment, the furnish is not contacted with an FCC at Block 125.

In the embodiment of FIG. 1, the furnish may be distributed to form a mat at Block 130. In an embodiment, the furnish may be distributed, for example, on a continuously-moving fine mesh screen (which may be referred to as a wire). Distribution of the furnish on such a wire may allow at least a portion of the liquid (e.g., water) to dissipate, escape, and/or otherwise be removed (e.g. via gravity, vacuum, or suction), leaving behind a mat comprising the fibers.

In the embodiment of FIG. 1, additionally or optionally, the mat may be contacted with an FCC at Block 135. In an embodiment where the fibers were previously contacted with an FCC (e.g., at Block 125), the mat may additionally be contacted with an FCC at Block 135. In such an embodiment, the FCC with which the mat is contacted at Block 135 may be the same or a different FCC than that with which the fibers were previously contacted (e.g., at Block 125). In an embodiment where the mat is contacted with an FCC, the FCC may be contacted with the mat in any suitable fashion. For example, the FCC may be applied to a formed mat by spraying a solution of the FCC onto the mat, by soaking the mat in an FCC-solution, or by any other appropriate method of treatment. In an embodiment, the FCC may be applied as at least a part of the binder emulsion. In an alternative embodiment, the mat may not be contacted with an FCC at Block 135. Instead, the binder emulsion comprising binder or binding agent may be applied to the mat prior to application of the FCC. In an embodiment, one or more additional suitable additives as discussed herein may be included in the binder emulsion. In an embodiment, the water in the binder emulsion may be present in an amount of from about 70% to about 99% based on a wet weight basis, alternatively from about 73% to about 87%, alternatively from about 76% to about 84%. In an embodiment, the water constitutes the remainder of the emulsion when all other components of the binder emulsion are accounted for.

In the embodiment of FIG. 1, the mat may be dried at Block 140. In an embodiment, the mat may be dried, for example, by heating the mat, introducing the mat into a low-pressure or negative pressure environment, subjecting the mat to air movement, or combinations thereof. Drying the mat may remove substantially all of the liquid present in the mat, leaving behind a dried fiber mat or filter media (e.g. an FCC-treated WNM).

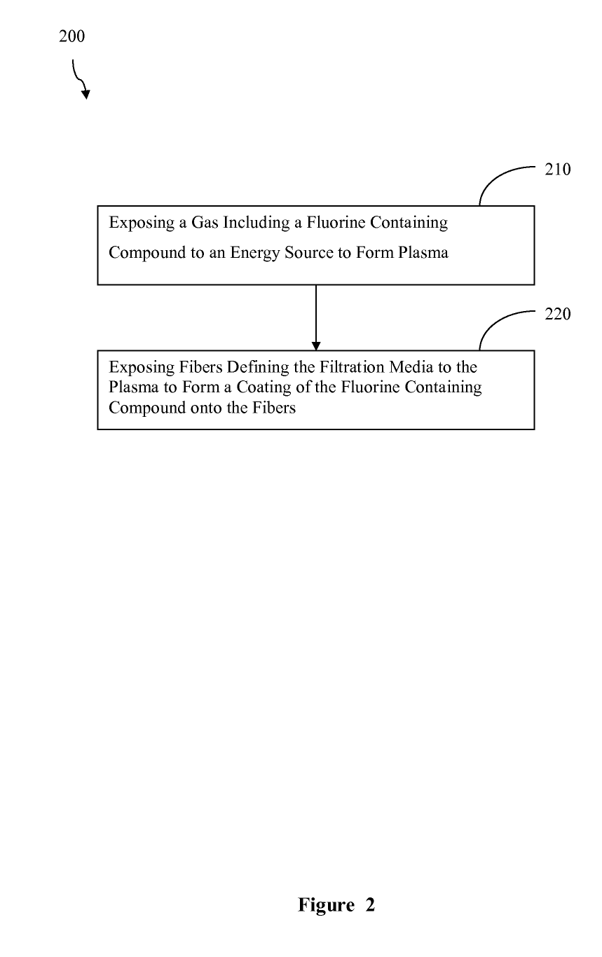

In the embodiment of FIG. 1, additionally or optionally, the filter media may be contacted with an FCC at Block 145. In an embodiment where the fibers and/or mat were previously contacted with an FCC (e.g., at Block 125 and/or Block 135), the filter media may additionally be contacted with an FCC at Block 145. In such an embodiment, the FCC with which the filter media is contacted at Block 145 may be the same or a different FCC than that with which the fibers were previously contacted (e.g., at Block 125 and/or Block 135). In an embodiment where the filter media is contacted with an FCC, the FCC may be contacted with the filter media in any suitable fashion. For example, the FCC may be applied to a formed mat by spraying a solution of the FCC onto the filter media and subsequently dried. In an alternative embodiment, the filter media may not be contacted with an FCC at Block 145. Referring now to FIG. 2, there is shown an alternative FMF process generally designated by reference numeral 200. In this embodiment, a filter media or the fibers used to form the media prior to media formation are subjected to a plasma deposition process to deposit fluorinated carbon polymeric compounds thereon. The process generally includes exposing a gas comprising a fluorine containing compound to an energy source to form a plasma as in step 210 followed by exposing fibers defining the non-woven liquid filtration media to the plasma to form a coating of the fluorine containing compound on the fibers as in step 220.

The selection of the monomers to form the fluorinated polymeric compounds and the plasma process conditions are generally selected that the presence of a free radical initiator is not needed. Suitable monomers are those that undergo plasma polymerization or modification of the surface to form a suitable polymeric coating layer or surface modification on the surface of the filtration media may suitably be used. Examples of such monomers include those known in the art to be capable of producing hydrophobic fluorinated polymeric coatings on substrates by plasma polymerisation including, for example, fluorinated and perfluorinated carbon compounds. Advantageously, plasma deposition can be used to provide a monolayer of the fluorine containing compound on the fibers.

In general, the filtration media to be treated is placed within a plasma chamber together with the fluorine containing material to be deposited in a gaseous state, a glow discharge is ignited within the chamber and a suitable voltage is applied, which may be pulsed or continuous. The fluorinated polymeric coating may be produced under both pulsed and continuous-wave plasma deposition conditions but pulsed plasma may be preferred as this allows closer control of the coating, and so the formation of a more uniform polymeric structure.

Precise conditions under which the plasma polymerization takes place in an effective manner will vary depending upon factors such as the nature of the polymer, the filtration media treated including both the material from which it is made and the pore size etc. and will be determined using routine methods and/or the techniques.

Suitable plasmas for use in the method of the invention include non-equilibrium plasmas such as those generated by radiofrequencies (RF), microwaves or direct current (DC). They may operate at atmospheric or sub-atmospheric pressures as are known in the art. In some embodiments, they are generated by radiofrequencies (RF).

In an embodiment, the filter media, (e.g., the FCC-treated WNM) may undergo various additional processing, for example, such that that the filter media may be configured for operation as a filter. In an embodiment, a filter media that has been configured for use in a filter may hereinafter be referred to as formed filter material (FFM).

In an embodiment, the filter media may be wound onto a core in roll form. In an embodiment, the filter media rolls are collated with or laminated onto one or more additional layers to form the FFM. In an embodiment, the filter media may be laminated onto a backer, a wire support, a glass or microglass support layer, or combinations thereof to form the FFM.

In an embodiment, the FFM may comprise a plurality of fiber layers. Such a plurality of layers may be the same or may vary as to the fiber used, density, fiber size, pore size, structural rigidity, or combinations of these and other variables. For example, a filter media may comprise two or more layers, each layer having heavier or lighter fibers relative to the other layer. In such an embodiment, the two or more layers may be provided together as a composite, with each layer of the composite having properties as described herein. Alternatively, the first and second layers may be co-formed on a continuous production line.

In an embodiment, a filter media (e.g., the FCC-treated WNM) may be further processed by pleating, folding, corrugating, or the like. In such an embodiment, the filter media may be formed into a pleated, accordion, or otherwise folded configuration. Not intending to be bound by theory, for high efficiency filters which must be constrained within a nominal filter area, pleating a filter media may provide a relatively higher exposed surface area in comparison to a flat filter media. Pleating is described for instance in U.S. Pat. No. 3,921,432, which is, and other references which are already, incorporated by reference in their entirety. In an embodiment, such a pleated or otherwise folded filter media may be held or otherwise disposed with in a frame, for example, a cartridge form, as would be appreciated by one of ordinary skill in the art viewing this disclosure.

In an embodiment, the filter media (e.g., the FCC-treated WNM) may be incorporated into a filter element having a generally cylindrical configuration and/or into a suitable housing (e.g., a canister), for example, of the type which may be suitable for hydraulic and other applications. The cylindrical filter element may include a steel support mesh that may provide pleat support and spacing, and/or which protects against damage to the filter media during handling and/or installation. The steel support mesh may be positioned as an upstream and/or downstream layer. The filter element may also include upstream and/or downstream support layers that can protect the filter media during pressure surges. These layers can be combined with filter media that may include two or more layers as noted above.

In an embodiment, a filter media (e.g., the FCC-treated WMN), for example, which may have been formed into a FFM, may be employed in a filtration application (e.g., to remove contamination in a variety of applications). Depending on the application, a filter media may be designed to have different performance characteristics. In an embodiment, a filter media may be designed and/or configured to have performance characteristics suitable for hydraulic applications, for example, for the removal of contaminants from pressurized hydraulic fluids. Examples of uses of hydraulic filters (e.g., high-, medium-, and low-pressure filters) include but are not limited to mobile and industrial filters. While the filter media may have a variety of desirable properties and characteristics which make it particularly well-suited for hydraulic applications, it should be understood that the filter media described herein are not limited to hydraulic applications, and that the filter media may be employed in other applications including but not limited to filtration of various other liquids. Examples of uses of non-hydraulic filters include but are not limited to fuel filters (e.g., automotive fuel filters), oil filters (e.g., tube oil filters or heavy duty lube oil filters), chemical processing filters, industrial processing filters, medical filters (e.g., filters for blood), and water filters. In an embodiment, a filter media of the type described herein may be used as coalescing filter media.

In an embodiment, a filter media (e.g., the FCC-treated WMN), for example, which may have been formed into a FFM, may be employed in a hydraulic filtration application. In such an embodiment, the FFM may comprise a suitable configuration for incorporation into a hydraulic system, for example, as described above. Such hydraulic systems may include open and closed circuit systems comprising various configurations of hydraulic pumps, control valves, reservoirs, accumulators, actuators (e.g., hydraulic cylinders, hydraulic motors, hydrostatic transmissions, swashplates, or the like), conduits (e.g., pipes, hydraulic hoses), seals, fittings, and connections, and combinations thereof. A suitable hydraulic fluid may be circulated within such a hydraulic system, as will be appreciated by one of skill in the art viewing this disclosure.

In an embodiment, the FFM may be incorporated into such a hydraulic system, for example, such that the filter media is in fluid communication with the hydraulic fluid, and the hydraulic fluid pumped or otherwise circulated through the filter media. Flow of the hydraulic fluid via the FFM (e.g., through the filter media) may be continued until cleaning or replacement is necessitated (e.g., upon indication that flow via the filter media is less than a desirable threshold and/or upon reaching a replacement, usage, or service interval).

### EXAMPLES

One or more embodiments having been generally described, the following examples are given as particular embodiments of the disclosure and to demonstrate the practice and advantages thereof. It is understood that the examples are given by way of illustration and are not intended to limit the specification or the claims in any manner.

### Example 1

In order to demonstrate the effect of the addition of an FCC to a filtration media, multi-pass tests were run on samples of filter media of the type described herein. Handsheets were prepared at a nominal basis weight of 42 lb/3000 ft². The sheets were composed of 3%, weight basis of total fibers, of type EP043 polyethylene terephthalate fibers, commercially available from Kuraray, and 97%, weight basis of total fibers, of a blend of commercially available Manville 206 and 210X glass fibers. The blend of glass fibers was chosen to produce a finished sheet with a nominal beta ratio of 200 at 10 microns. This combination of fibers and the efficiency and basis weight of the resulting handsheet was chosen because it is representative of what is commonly used in those industrial applications as would be appropriate for the filter media disclosed herein.

Sample sheets were made using an epoxy binder comprising a blend of 75%, on a total solids content basis, of Epirez 5520W60 epoxy resin and 25%, on a total solids content basis, of Epikure 8537WY60 amine curing agent, both commercially available from Hexion. Sample sheets were also made using a latex binder comprising a blend of 50%, on a total solids content basis, of Hycar 26172 and 50%, on a total solids content basis, of Hycar 26349 acrylic ester copolymers, both commercially available from Lubrizol Corporation. The emulsions were diluted with water and sprayed onto the formed fibrous sheets prior to drying to achieve a loss on ignition (LOI) on the final sheet of a nominal 10% of the total sheet weight. The sheets thus produced comprise the epoxy and latex control samples. The epoxy binder and the latex binder were also mixed with Zonyl 7040 Fabric Protector (an aqueous emulsion of fluoroacrylate copolymers commercially available from DuPont), and diluted with water to yield emulsions comprising 86% of epoxy solids or latex solids and 14% Zonyl 7040 solids in finished emulsion. The finished emulsions were sprayed onto the formed fibrous sheets prior to drying to achieve a loss on ignition (LOI) on the final sheet of a nominal 10% of the total sheet weight. In addition, Repellent 300-LF (a fluoroacrylate polymer emulsion commercially available from Performance Chemicals), was added to the forming water for the handsheet at 1.88% of the nominal sheet weight just prior to formation of the fibrous mat. The sheets thus produced comprise the FCC-treated samples.

Table 1 shows the results on the relevant sheet properties of this experiment.

TABLE 1

| | | FCC- | | FCC- |
|---|---|---|---|---|
| | Epoxy | Treated | Latex | Treated |
| | Control | Epoxy | Control | Latex |
| Basis Weight (lb/3000 ft²) | 40.5 | 40.6 | 42.0 | 41.0 |
| Caliper @ 8 psi (mils) | 17.2 | 18.0 | 19.0 | 17.8 |
| Q127 Resistance (mm H₂0) | 5.75 | 5.70 | 5.65 | 5.90 |
| LOI (%) | 9.1 | 9.4 | 12.1 | 8.4 |
| DHC @ 2 bar (g/m²) | 73.5 | 147.0 | 67.0 | 131.0 |
| β_{x(c)} @ 200 (μm) | 10.3 | 4.6 | 8.7 | 4.0 |

As demonstrated in Table 1, the dirt holding capacity and efficiency demonstrated by the FCC-treated handsheets as indicated by the beta ratio are both significantly improved over the otherwise similar handsheets that were not treated with an FCC.

### Example 2

Example 2 demonstrates the effect of the addition of an FCC to a filtration media similarly to Example 1, but using additional grades of filter media. Testing was conducted as in Example 1 with grades 9106 and 9106R filter media, which are nominally 9 micron efficiency, filter media having an epoxy binder, commercially available from Lydall, Inc. Grades 9106 and 9106R are manufactured from the same materials, by the same methods, and are otherwise similar with the exception that the 9106R binder emulsion comprises 86% epoxy and 14% Zonyl 7040 whereas the 9106 comprises 100% epoxy. In addition, the 9106R comprises Repellent 300-LF in a range of from about 1.5%-2.0% of the nominal sheet weight as an additive to the forming water. Table 2 shows the results of the testing.

TABLE 2

| | | 9106R | 9106 |
|---|---|---|---|
| Basis Weight (lb/3000 ft²) | | 60.7 | 59.4 |
| Caliper @ 8 psi (mils) | | 25.2 | 23.7 |
| LOI (%) | | 16.3 | 16.21 |
| Q127 Resistance (mm H₂0) | | 5.8 | 6.1 |
| FSMPDHC | @ 2 bar | 218.2 | 109.2 |
| (g/m²) | @ 5 bar | 286.9 | 149.6 |
| β_{x(c)} (μm) @ | 200 | 4.6 | 8.9 |
| | 1000 | 7.8 | 13.3 |

As shown above, the 9106R filter media, which was treated with an FCC, demonstrates a significantly better flatsheet multi-pass dirt holding capacity (FSMPDHC) in comparison to the otherwise similar 9106 filter media which was not treated with an FCC.

### Example 3

Example 3 demonstrates the effect of the addition of an FCC to a filtration media similarly to Example 1 and 2, but using two additional grades of filter media. Testing was conducted as in Examples 1 and 2, with grade 9010, which is a nominally 10 micron efficiency filter media having a latex binder, commercially available from Lydall Inc., and with a grade designated Variation-0, which was manufactured from the same materials by the same methods, and is otherwise similar to grade 9010 with the exception that its binder emulsion comprises 86% latex and 14% Zonyl 7040 whereas grade 9010 comprises 100% latex. In addition, Variation-0 comprises 1.5%-2.0% Repellent 300-LF of the nominal sheet weight as an additive to the forming water. Table 3 shows the results of the testing.

TABLE 3

| | 9010 | Var.- 0 |
|---|---|---|
| Basis Weight (lb/3000 ft²) | 51.7 | 53.2 |
| Caliper @ 8 psi (mils) | 23.0 | 23.1 |
| SAD @ 8 psi (mils) | 2.25 | 2.30 |
| Q127 Resistance (mm H₂0) | 3.81 | 4.2 |
| β_{x(c)} @ 200 (μm) | 13.4 | 12.6 |
| DHC @ 2 bar (g/m2) | 150.7 | 249.8 |
| LOI (%) | 9.67 | 11.5 |

Example 3 demonstrates that addition of an FCC (as shown by Variation-0) has a substantial positive impact on flat-sheet dirt holding capacity.

### Example 4

Example 4 demonstrates the effect of the addition of an FCC to a filtration media using pulsed plasma vacuum apparatus. The pulsed plasma vacuum apparatus deposited a nanometer-thin perfluorodecyl acrylate polymer onto the filter media. Testing was conducted as in the prior Examples with grade 9010 of Example 3 and with grade 9006, which is a nominally 6 micron efficiency filter media having a latex binder, commercially available from Lydall Inc. Table 4 shows the results of the testing.

TABLE 4

| | 9006 | | 9010 | |
|---|---|---|---|---|
| | Untreated | Treated | Untreated | Treated |
| Basis Weight (lb/3000 ft2) | 52.2 | 52.5 | 51.7 | 53.3 |
| Caliper @ 8 psi (mils) | 20.7 | 20.3 | 23.0 | 23.6 |
| Q127 Resistance @ 2 bar (g/m2) | 7.3 | 7.4 | 4.0 | 4.4 |
| DHC @ 2 bar (g/m²) | 137.1 | 223.0 | 150.7 | 247.5 |
| β_{x(c)} @ 200 (μm) | 7.6 | <4.0 | 13.4 | 10.5 |

As shown above, the media treated with the FCC applied by pulsed plasma vacuum nano-coating technology has a substantial positive impact on both dirt holding capacity and efficiency.

While embodiments have been shown and described, any number or type of modifications can be made by one skilled in the art without departing from the spirit and teachings of the disclosure. The embodiments described herein are exemplary only, and are not intended to be limiting. Many variations and modifications of the embodiments disclosed herein are possible and are within the scope of the invention. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). Use of the term “optionally” with respect to any element of a claim is intended to mean that the subject element is required, or alternatively, is not required. Both alternatives are intended to be within the scope of the claim. Use of broader terms such as comprises, includes, having, etc. should be understood to provide support for narrower terms such as consisting of, consisting essentially of, comprised substantially of, etc.

Accordingly, the scope of protection is not limited by the description set out above but is only limited by the claims which follow, that scope including all equivalents of the subject matter of the claims. Each and every claim is incorporated into the specification as an embodiment of the present disclosure. Thus, the claims are a further description and are an addition to the preferred embodiments of the present disclosure. The discussion of a reference herein is not an admission that it is prior art to the present disclosure, especially any reference that may have a publication date after the priority date of this application. The disclosures of all patents, patent applications, and publications cited herein are hereby incorporated by reference, to the extent that they provide exemplary, procedural or other details supplementary to those set forth herein.

What is claimed is:

1. A liquid filtration media comprising:
a wet laid non-woven filter comprising plurality of fibers having a coating thereon of a fluorine containing compound.

2. The liquid filtration media of claim 1, wherein the fluorine-containing compound is present in an amount effective to modify the surface energy of the liquid filtration media.

3. The liquid filtration media of claim 1, wherein the fluorine-containing compound comprises a fluoropolymer.

4. The liquid filtration media of claim 3, wherein the fluoropolymer comprises a fluoroacrylate polymer, a fluoroalkyl acrylate polymer, a fluoroalkyl methacrylate polymer, or combinations thereof.

5. The liquid filtration media of claim 1, wherein the plurality of fibers comprise glass fibers, polyolefin fibers, and combinations thereof.

6. The liquid filtration media of claim 1, wherein the fluorochemical containing compound comprises polytetrafluoropolyethylene.

7. The liquid filtration media of claim 1, wherein the liquid filtration media exhibits an increase in efficiency relative to the liquid filtration media without the coating of the fluorine containing compound.

8. The liquid filtration media of claim 1, wherein the liquid filtration media exhibits an increase in dirt-holding capacity relative to the liquid filtration media without the coating of the fluorine containing compound.

9. The liquid filtration media of claim 1, wherein the liquid filtration media exhibits an increase in beta ratio relative to the liquid filtration media without the coating of the fluorine containing compound.

10. A method of forming fibrous non-woven liquid filtration media comprising:
dispersing fibers in a liquid to form a furnish;
subjecting the furnish to a moving forming screen to form a fibrous web;
applying a binder to the fibrous web;
drying the fibrous web to form a fibrous non woven mat, wherein a fluorine containing compound is supplied in the furnish; and
incorporating the fibrous non woven mat into the fibrous non woven liquid filtration media.

11. The method of claim 10, wherein the filtration media within the liquid filter exhibits an increase in dirt-holding capacity relative to the fibrous non-woven liquid filtration media without the fluorine containing compound.

12. The method of claim 10, wherein the filtration media within the liquid filter exhibits an increase in beta ratio relative to the fibrous non-woven liquid filtration media without the fluorine containing compound.

13. The method of claim 10, wherein the fluorine containing compound comprises a fluoropolymer.

14. The method of claim 13, wherein the fluoropolymer comprises a fluoroacrylate polymer, a fluoroalkyl acrylate polymer, a fluoroalkyl methacrylate polymer, or combinations thereof.

15. The method of claim 10, wherein fibers comprise glass fibers, polyolefin fibers, and combinations thereof.

16. A liquid filtration media comprising:
a wet-laid non-woven glass fiber mat having a coating of a fluorine-containing compound applied to the glass fiber mat.

17. The liquid filtration media of claim 16, wherein the fluorine containing compound applied to the glass fiber mat is a monolayer of the fluorine containing compound.

18. A method of forming fibrous non-woven liquid filtration media comprising:
exposing a gas comprising a fluorine containing compound to an energy source to form a plasma; and
exposing fibers defining the non-woven liquid filtration media to the plasma to form a coating of the fluorine containing compound on the fibers.

19. The method of claim 18, wherein the filtration media within the liquid filter exhibits an increase in dirt-holding capacity relative to the fibrous non-woven liquid filtration media without the fluorine containing compound.

20. The method of claim 18, wherein the filtration media within the liquid filter exhibits an increase in beta ratio relative to the fibrous non-woven liquid filtration media without the fluorine containing compound.

21. The method of claim 18, wherein fibers comprise glass fibers, polyolefin fibers, and combinations thereof.
